(19) United States
(12) Patent Application Publication
(10) Pub. No.: US 2026/0323177 A1
(43) Pub. Date: Oct. 15, 2026

(54) IMAGE SENSING DEVICE AND IMAGING SYSTEM

(71) Applicant: SK hynix Inc., Gyeonggi-do (KR)

(72) Inventor: Kazuhiro YAHATA, Tokyo (JP)

(21) Appl. No.: 19/642,629

(22) Filed: Apr. 9, 2026

(30) Foreign Application Priority Data
Apr. 9, 2025 (KR) 10-2025-0046010

(51) Int. Cl. H04N 25/61; H04N 25/13; H04N 25/40; H04N 25/707; H04N 25/78

(52) U.S. Cl. CPC H04N 25/61; H04N 25/134; H04N 25/41; H04N 25/707; H04N 25/78

(57) ABSTRACT

An image sensing device includes a first flare detection photodiode; a first mask disposed over the first flare detection photodiode; a second flare detection photodiode disposed adjacent to the first flare detection photodiode; and a second mask disposed over the second flare detection photodiode and configured to be larger than the first mask.

### CROSS-REFERENCE TO RELATED APPLICATION

This patent application claims the priority and benefits of Korean patent application No. 10-2025-0046010, filed on Apr. 9, 2025, the disclosure of which is incorporated herein by reference in its entirety.

### TECHNICAL FIELD

The technology and embodiments of the present disclosure generally relate to an image sensing device and an imaging system.

### BACKGROUND

An imaging system is a device for capturing optical images by converting light into electrical signals using a photosensitive semiconductor material which reacts to light. With the development of automotive, medical, computer and communication industries, the demand for high-performance imaging systems is increasing in various fields such as smartphones, digital cameras, game machines, IoT (Internet of Things), robots, security cameras and medical micro cameras.

When an image is captured by the imaging system, lens flare may occur due to strong light. In the event of lens flare, issues such as reduction in image contrast may arise, and thus it is necessary to detect occurrence of such lens flare.

### SUMMARY

Various embodiments of the present disclosure relate to an imaging device including at least one flare detection pixel, which can determine occurrence or non-occurrence of flare using the flare detection pixel.

Various embodiments of the present disclosure relate to an image sensing device including a mask that blocks a portion of light incident upon photodiodes.

In accordance with an embodiment of the present disclosure, an image sensing device may include a first flare detection photodiode; a first mask disposed over the first flare detection photodiode; a second flare detection photodiode disposed adjacent to the first flare detection photodiode; and a second mask disposed over the second flare detection photodiode and configured to be larger than the first mask.

In some embodiments, the first mask may block a portion of light incident upon the first flare detection photodiode from an exit pupil; and the second mask may block a portion of light incident upon the second flare detection photodiode from the exit pupil.

In some embodiments, the image sensing device may further include a first filter disposed over the first flare detection photodiode and disposed adjacent to the first mask; and a second filter disposed over the second flare detection photodiode and disposed adjacent to the second mask.

In some embodiments, the first filter and the second filter may be transparent filters.

In some embodiments, the image sensing device may further include a first microlens disposed over the first mask and shifted by an offset from a central axis of the first flare detection photodiode; a second microlens disposed over the second mask and shifted by the offset from a central axis of the second flare detection photodiode; an image photodiode configured to generate an image signal; a third filter disposed over the image photodiode; and a third microlens disposed over the third filter and shifted by the offset from a central axis of the image photodiode.

In some embodiments, the third filter may be a color filter including at least one color among red, green, and blue.

In some embodiments, the offset may correspond to an angle of incidence of light incident upon the first flare detection photodiode, the second flare detection photodiode, and the image photodiode from an exit pupil.

In some embodiments, the first flare detection photodiode and the second flare detection photodiode may be disposed inside an image circle.

In some embodiments, the first flare detection photodiode and the second flare detection photodiode may be disposed inside an optical black region.

In some embodiments, the first flare detection photodiode and the second flare detection photodiode may be disposed outside an optical black region.

In some embodiments, the first mask may be disposed at a position closest to an exit pupil among upper regions of the first flare detection photodiode.

In some embodiments, the second mask may be disposed at a position closest to an exit pupil among upper regions of the second flare detection photodiode.

In some embodiments, the first mask and the second mask may be metal masks.

In accordance with another embodiment of the present disclosure, an imaging system may include an image sensing device and an image processing device. The image sensing device may include a first flare detection pixel including a first mask, which blocks a portion of light from an exit pupil, detects flare light, and generates a first flare detection signal; a second flare detection pixel including a second mask, which blocks a portion of light from the exit pupil, detects the flare light, and generates a second flare detection signal; and a readout circuit configured to generate a first flare detection pixel value based on the first flare detection signal and to generate a second flare detection pixel value based on the second flare detection signal. The image processing device may determine whether flare has occurred based on the first flare detection pixel value and the second flare detection pixel value.

In some embodiments, the first flare detection pixel and the second flare detection pixel may be disposed inside an image circle.

In some embodiments, the first flare detection pixel and the second flare detection pixel may be disposed outside an optical black region.

In some embodiments, the first flare detection pixel and the second flare detection pixel may be disposed inside an optical black region.

In some embodiments, the image processing device may determine that flare has occurred when the first flare detection pixel value or the second flare detection pixel value is greater than a first threshold.

In some embodiments, the image processing device may determine that the flare has occurred, when a ratio of a first value obtained by subtracting a black level from the first flare detection pixel value, to a second value obtained by subtracting the black level from the second flare detection pixel value, is less than a second threshold or when the ratio of the first value to the second value is greater than a third threshold.

In accordance with another embodiment of the present disclosure, an imaging system may include an image sensing device and an image processing device. The image sensing device includes a first flare detection photodiode configured to generate a first flare detection signal; a second flare detection photodiode configured to generate a second flare detection signal; a first mask disposed over the first flare detection photodiode; a second mask disposed over the second flare detection photodiode; and a readout circuit configured to generate a first flare detection pixel value based on the first flare detection signal and to generate a second flare detection pixel value based on the second flare detection signal. The image processing device may determine whether flare has occurred based on the first flare detection pixel value, the second flare detection pixel value, and a black level.

It is to be understood that both the foregoing general description and the following detailed description of the embodiments of the present disclosure are illustrative and are intended to provide further description of the embodiments as claimed.

### BRIEF DESCRIPTION OF THE DRAWINGS

The above and other features and beneficial aspects of the embodiments of the present disclosure will become readily apparent with reference to the following detailed description when considered in conjunction with the accompanying drawings.

FIG. 1 is a block diagram illustrating an imaging system according to an embodiment of the present disclosure.

FIG. 2 is a diagram illustrating an image sensing device according to an embodiment of the present disclosure.

FIG. 3 is a diagram illustrating a pixel region according to an embodiment of the present disclosure.

FIG. 4 is a diagram illustrating a pixel according to an embodiment of the present disclosure.

FIG. 5 is a diagram illustrating a pixel according to an embodiment of the present disclosure.

FIG. 6 is a diagram illustrating sensitivity according to an embodiment of the present disclosure.

FIG. 7 is a diagram illustrating an offset according to an embodiment of the present disclosure.

FIG. 8 is a diagram illustrating sensitivity according to an embodiment of the present disclosure.

FIG. 9 is a block diagram showing a computing device corresponding to the image processing device of FIG. 1 according to an embodiment of the present disclosure.

### DETAILED DESCRIPTION

The present disclosure includes embodiments of an image sensing device and an imaging system that may be used in configurations to substantially address one or more technical or engineering issues and to mitigate limitations or disadvantages encountered in some image sensing devices. Some embodiments of the present disclosure relate to an imaging device including at least one flare detection pixel, which can determine occurrence or non-occurrence of flare using the flare detection pixel. Some embodiments of the present disclosure relate to an image sensing device including a mask that blocks a portion of light incident upon photodiodes. In recognition of the issues above, the embodiments may advantageously provide an imaging system that can determine whether flare has occurred by using pixel values of flare detection pixels. Since the image sensing device includes a mask that blocks a portion of the light incident upon photodiodes, the image sensing device may accurately determine occurrence or non-occurrence of flare by using the mask.

Reference will now be made in detail to the embodiments of the present disclosure which are illustrated in the accompanying drawings. Wherever possible, the same reference numbers will be used throughout the drawings to refer to the same or like parts. While the embodiments are susceptible to various modifications and alternative forms, specific embodiments thereof are shown in the drawings. However, the embodiments should not be construed as being limited to the embodiments set forth herein.

Hereinafter, various embodiments will be described with reference to the accompanying drawings. However, it should be understood that the embodiments are not limited to specific embodiments, but includes various modifications, equivalents and/or alternatives of the embodiments. The embodiments of the present disclosure may provide a variety of advantageous effects capable of being directly or indirectly recognized by one of ordinary skill in the art.

Hereinafter, embodiments of the present disclosure will be described in detail with reference to the accompanying drawings so that the scope of the present disclosure may be easily realized by those skilled in the art. However, the embodiments of the present disclosure may be achieved in various different forms and are not limited to the embodiments described herein.

In the following description of embodiments of the present disclosure, a detailed description of known functions and configurations incorporated herein will be omitted when it may make the subject matter of the present disclosure rather unclear. In the drawings, parts that are not related to a description of the present disclosure are omitted to clearly describe the embodiments and similar reference numbers will be used throughout this disclosure to refer to similar parts.

In the present disclosure, when a component is referred to as being “connected”, “coupled”, or “joined” to another component, it may include not only a direct connection relationship but also an indirect connection relationship in which another component is present therebetween. In addition, when a component “comprises”, “includes” or “has” another component, this means that the component does not exclude other components unless specifically stated but may further include other components.

In the present disclosure, terms such as “first”, “second”, etc. are used only to distinguish one element from other elements and are not used to limit elements, and unless otherwise specified, the terms do not limit an order or importance, etc. of elements. Accordingly, within a scope of the present disclosure, a first element in an embodiment may be referred to as a second element in another embodiment and likewise, a second element in an embodiment may be referred to as a first element in another embodiment.

In the following description, components are discriminated from each other to clearly describe their characteristics, but this does not mean that they are necessarily physically separated. That is, a plurality of components may be integrated into one hardware or software module and one component may be divided into a plurality of hardware or software modules. Accordingly, integrated or divided embodiments are within the scope of the present disclosure even if not specifically stated.

In the following description, components described with reference to various embodiments are not all necessarily required and some components may be selectively used. Accordingly, embodiments composed of some of the components described in one embodiment are also within the scope of the present disclosure. Further, embodiments implemented by adding components to various embodiments are also within the scope of the present disclosure.

In the present disclosure expressions of positional relationships used in the present specification such as “top”, “upper”, “bottom”, “lower”, “left”, “right”, etc. are employed for the convenience of description, and when the drawings illustrated in the present disclosure are viewed in reverse, the positional relationships described may be interpreted in the opposite way.

In the present disclosure, each of phrases such as “A or B”, “at least one of A and B”, “at least one of A or B”, “A, B or C”, “at least one of A, B and C”, “and “at least one of A, B, or C” may include any one or all possible combinations of the items listed together in the corresponding one of the phrases. In the description of the present disclosure, the term “and/or” may include a combination of a plurality of items or any one of a plurality of listed items. For example, “A or B” may include “only A”, “only B”, or “both A and B”.

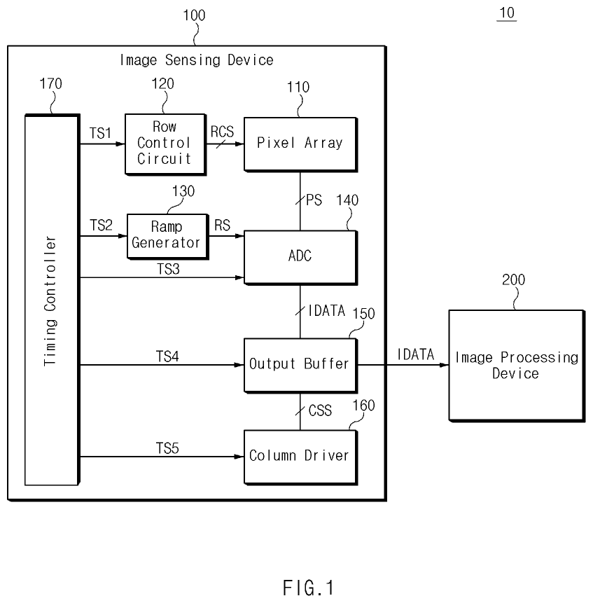

Hereinafter, embodiments of the present disclosure will be specifically described with reference to FIGS. 1 to 9.

FIG. 1 is a block diagram illustrating an imaging system 10 according to an embodiment of the present disclosure.

Referring to FIG. 1, the imaging system 10 may refer to a device, for example, a digital still camera for photographing still images or a digital video camera for photographing moving images. For example, the imaging system 10 may be implemented as a Digital Single Lens Reflex (DSLR) camera, a mirrorless camera, or a smartphone, but is not limited thereto. The imaging system 10 may include a device having an image pickup element such that the device can capture (or photograph) a target object and can thus create an image of the target object.

The imaging system 10 may include an image sensing device 100 and an image processing device 200. The image processing device 200 may correspond to an image signal processor (ISP).

The image sensing device 100 may be a complementary metal oxide semiconductor image sensor (CIS) configured to convert an incident light into an electrical signal. The image sensing device 100 may include a pixel array 110, a row control circuit 120, a ramp generator 130, an analog-to-digital converter (ADC) 140, an output buffer 150, a column driver 160, and a timing controller 170. The components of the image sensing device 100 are illustrated in FIG. 1 and the embodiments encompass numerous other changes, substitutions, variations, alterations, and modifications.

The pixel array 110 may include a plurality of pixels arranged in rows and columns. In one embodiment, the plurality of pixels may be arranged in a two-dimensional (2D) pixel array including rows and columns. In another embodiment, the plurality of image pixels may be arranged in a three-dimensional (3D) pixel array. The plurality of pixels may convert an optical signal into an electrical signal on a pixel basis or a pixel group basis, where the pixels in a pixel group share at least certain internal circuitry. The pixel array 110 may receive row control signals (RCS), including a row selection signal, a pixel reset signal and a transfer signal, from the row control circuit 120. Upon receiving the RCSs, corresponding pixels in the pixel array 110 may be activated to perform the operations corresponding to the row selection signal, the pixel reset signal, and the transfer signal.

Each pixel in the pixel array 110 may have at least two different sensitivities. Here, the sensitivity may mean an increase in amount of image data IDATA (or an increase in amount of a response) with respect to an increase in amount of the intensity of incident light. That is, as the sensitivity increases, the amount of increase in image data IDATA in response to an increase in the intensity of incident light increases. As the sensitivity decreases, the amount of increase in image data IDATA in response to an increase in the intensity of incident light decreases. In the present disclosure, the sensitivity may be determined by a conversion gain.

The row control circuit 120 may activate the pixel array 110 to perform specific operations on the pixels included in the corresponding row based on commands and control signals (TS1) provided by the timing controller 170. The row control circuit 120 may include a row driver. In some embodiments, the row control circuit 120 may select at least one pixel arranged in at least one row of the pixel array 110. The row control circuit 120 may generate a row selection signal to select at least one row among the plurality of rows. The row control circuit 120 may sequentially enable the pixel reset signal and the transfer signal for the pixels corresponding to the at least one selected row. Thus, a reference signal and an image signal, which are analog signals generated by each of the pixels of the selected row, may be sequentially transferred to the ADC 140. The reference signal may be an electrical signal that is provided to the ADC 140 when a sensing node of a pixel (e.g., a floating diffusion region) is reset, and the image signal may be an electrical signal that is provided to the ADC 140 when photocharges generated by the pixel are accumulated in the sensing node. The reference signal indicating unique reset noise of each pixel and the image signal indicating the intensity of incident light may be generically referred to as a pixel signal (PS).

The CMOS image sensor may use the correlated double sampling (CDS) to remove undesired offset values of pixels known as the fixed pattern noise by sampling a pixel signal (PS) twice to remove the difference between two samples. In one embodiment, the CDS may remove the undesired offset value of pixels by comparing pixel output voltages obtained before and after photocharges generated by incident light are accumulated in the sensing node such that only pixel output voltages based on the incident light can be measured. In some embodiments, the ADC 140 may sequentially sample and hold the reference signal and the image signal, which are provided from each of a plurality of column lines from the pixel array 110.

The ramp generator 130 may generate a ramp signal (RS) required for the analog-to-digital conversion operation of the ADC 140 upon receiving a timing signal (TS2) from the timing controller 170, and may supply the ramp signal to the ADC 140.

The ADC 140 may sample and hold the pixel signal (PS) from each column line of the pixel array 110 based on a timing signal (TS3) of the timing controller 170, may convert the resultant signal into digital signals, and may output the digital signals. In some embodiments, the ADC 140 may be implemented as a ramp-compare type ADC. The ramp-compare type ADC may include a comparator circuit for comparing the analog pixel signal (PS) with a ramp signal that ramps up or down over time, and a counter for performing counting until the ramp signal matches the analog pixel signal (PS).

The output buffer 150 may temporarily hold the column-based image data (i.e., data (IDATA) obtained through digital conversion of the pixel signal (PS)) provided from the ADC 140 to output the image data (IDATA). The image data IDATA output from the ADC 140 may be temporarily stored in the output buffer 150 based on a timing signal (TS4) of the timing controller 170. The output buffer 150 may provide an interface to compensate for differences in data rate or transfer rate between the image sensing device 100 and other devices.

The column driver 160 may select a column of the output buffer 150 based on a control signal (TS5) from the timing controller 170, and may control the output buffer 150 to sequentially output the image data IDATA, which are temporarily stored in the selected column of the output buffer 150. In some embodiments, upon receiving an address signal from the timing controller 170, the column driver 160 may generate a column selection signal (CSS) based on the address signal and may select a column of the output buffer 150, thereby outputting the image data IDATA as an output signal from the selected column of the output buffer 150.

The timing controller 170 may control operations of at least one of the row control circuit 120, the ramp generator 130, the ADC 140, the output buffer 150, or the column driver 160.

The timing controller 170 may provide at least one of the row control circuit 120, the ramp generator 130, the ADC 140, the output buffer 150, or the column driver 160 with a clock signal required for the operations of the respective components of the image sensing device 100, a control signal for timing control, and address signals for selecting a row or column. In some embodiments, the timing controller 170 may include a logic control circuit, a phase-locked loop (PLL) circuit, a timing control circuit, and a communication interface circuit.

The image processing device 200 may perform image signal processing on the image data IDATA received from the image sensing device 100. The image processing device 200 may reduce noise in the image data IDATA, and may perform various kinds of image signal processing, such as interpolation, synthesis, gamma correction, color filter array interpolation, color matrix, color correction, color enhancement, and lens distortion correction, for image-quality improvement of the image data IDATA. In addition, the image processing device 200 may compress image data that has been created by execution of image signal processing for image-quality improvement, such that the image processing device 200 can create an image file using the compressed image data. Alternatively, the image processing device 200 may recover image data from the image file. In this case, the format for compressing such image data may be a reversible format or an irreversible format. As an example of the compression format, for a still image, Joint Photographic Experts Group (JPEG) format, JPEG 2000 format, or the like may be used. In addition, for moving images, a plurality of frames may be compressed according to Moving Picture Experts Group (MPEG) standards to create moving image files. For example, image files may be created according to Exchangeable image file format (Exif) standards.

The image processing device 200 may generate an HDR image by synthesizing at least two images having different sensitivities. For example, the image sensing device 100 may output a low-sensitivity image generated from a low-sensitivity pixel (e.g., a low conversion gain (LCG) pixel) with a relatively lower sensitivity and a high-sensitivity image generated from a high-sensitivity pixel (e.g., a high conversion gain (HCG) pixel) with a relatively higher sensitivity. The image processing device 200 may combine the low-sensitivity image and the high-sensitivity image to generate an HDR image. Here, the low-sensitivity and the high-sensitivity may correspond to relative concepts, and the image sensing device 100 may generate image data IDATA having at least N different sensitivities, where N is an integer greater than or equal to 2. The image processing device 200 may generate HDR images from the image data IDATA.

The image processing device 200 may transmit the image data, for which the image processing operation has been completed, to a host device (not shown). The host device (not shown) may be a processor (e.g., an application processor) for processing the image-processed image data received from the image processing device 200, a memory (e.g., a non-volatile memory) for storing the image data, or a display device (e.g., a liquid crystal display LCD) for visually displaying the image data.

In addition, the image processing device 200 may transmit a control signal for controlling operations (e.g., whether or not to operate, an operation timing, an operation mode, etc.) of the image sensing device 100 to the image sensing device 100.

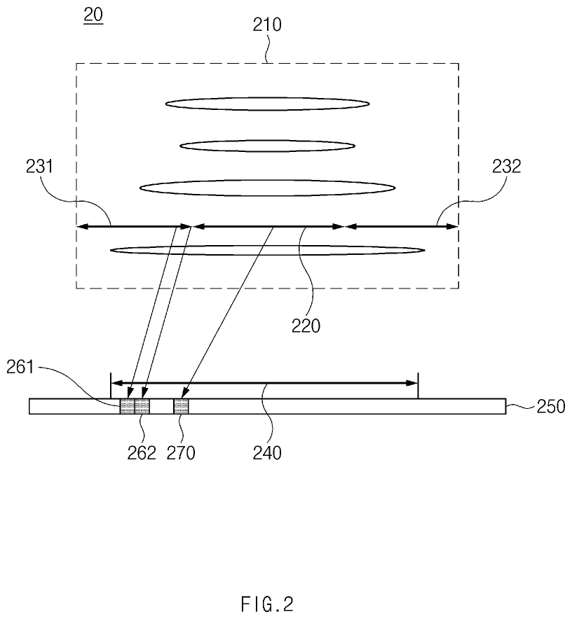

FIG. 2 is a diagram illustrating an image sensing device 20 according to an embodiment of the present disclosure. The image sensing device 20 corresponds to the image sensing device 100 of FIG. 1.

Referring to FIG. 2, the image sensing device 20 according to an embodiment of the present disclosure may include a main lens 210 and a pixel region 250.

The main lens 210 may include multiple lenses that collect light and direct the collected light to be incident upon the pixels.

Depending on the configuration of the main lens 210, the range of the exit pupil 220, outer sides (231, 232) of the exit pupil 220, and the range of the image circle 240 may be determined. In the imaging system, the path of light may be adjusted while passing through multiple lenses, and the position of an imaginary exit through which the light finally emerges after passing through the lenses may be referred to as an exit pupil 220. Accordingly, light is generally incident from the exit pupil 220 onto the pixel region 250; however, due to the occurrence of lens flare, there may also be light incident from the outer sides (231, 232) of the exit pupil 220 onto the pixel region 250. The image circle 240 may be disposed within a light incident area defined by the main lens 210.

The pixel region 250 may refer to a region in which pixels may be arranged. For example, the pixel region 250 may include flare detection pixels (261, 262) and at least one image pixel 270.

The flare detection pixels (261, 262) may refer to pixels that detect flare light. By detecting flare light, the flare detection pixels (261, 262) may generate a flare detection signal. More specific details regarding the configuration of the flare detection pixels (261, 262) will be described later.

The flare detection pixels (261, 262) may be disposed inside the image circle 240. Light may be incident from the outer sides (231, 232) of the exit pupil 220 toward the inside of the image circle 240. Therefore, since the flare detection pixel (261, 262) is disposed inside the image circle 240, the flare detection pixels (261, 262) can detect flare light.

The image pixel 270 may refer to a pixel that generates an image signal. The image signal may be used to generate an image. The image pixel 270 may be disposed inside the image circle 240.

Although not shown in FIG. 2, the image sensing device 20 may include a readout circuit. The readout circuit may generate pixel values based on signals received from the flare detection pixels (261, 262) and the image pixels 270. For example, the readout circuit may generate a flare detection pixel value based on the flare detection signal, and may generate an image pixel value based on the image signal.

The image processing device may determine that flare has occurred when the flare detection pixel value is equal to or greater than a first threshold. Here, the first threshold may be a value greater than a noise level. In addition, the image processing device may determine that flare has occurred when the ratio of the number of pixel values equal to or greater than the first threshold among multiple flare detection pixel values generated by multiple flare detection pixels is equal to or greater than a predetermined ratio. For example, when the ratio of pixel values equal to or greater than the first threshold among the flare detection pixel values is 10% or more, the image processing device may determine that flare has occurred, but the embodiments of the present disclosure are not limited thereto.

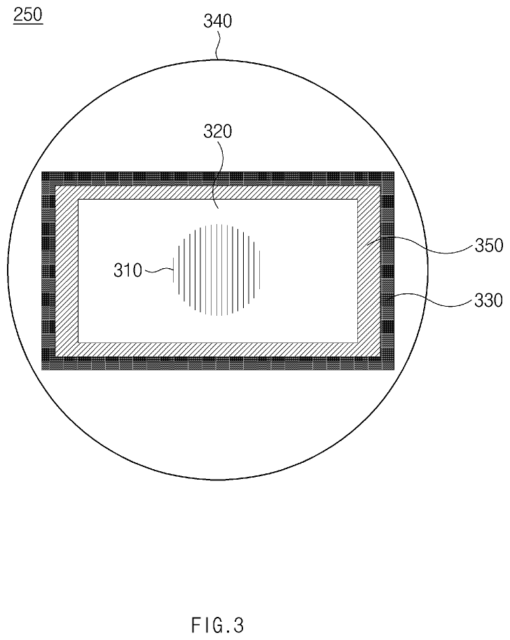

FIG. 3 is a diagram illustrating the pixel region 250 according to an embodiment of the present disclosure.

Hereinafter, the embodiment of FIG. 3 will be described with reference to FIG. 2.

Referring to FIG. 3, the pixel region 250 according to an embodiment of the present disclosure may include an image pixel region 320, an optical black region 330, and a flare detection pixel region 350. FIG. 3 is a top view of the pixel region 250 shown in FIG. 2. In FIG. 3, an exit pupil 310 corresponding to the exit pupil 220 of FIG. 2 and an image circle 340 corresponding to the image circle 240 of FIG. 2 are illustrated.

The image pixel region 320 may be a region in which image pixels are arranged.

The optical black region 330 may represent a region including pixels that are kept in a light-blocked state. Since light is blocked, the optical black region 330 may be used to measure a black level of the image sensing device, or may be used to remove noise from the image sensing device.

The flare detection pixel region 350 may be a region in which flare detection pixels are arranged. The flare detection pixel region 350 may be disposed inside the image circle 340. In addition, the flare detection pixel region 350 may be disposed inside the optical black region 330. Furthermore, the flare detection pixel region 350 may be located outside the image pixel region 320.

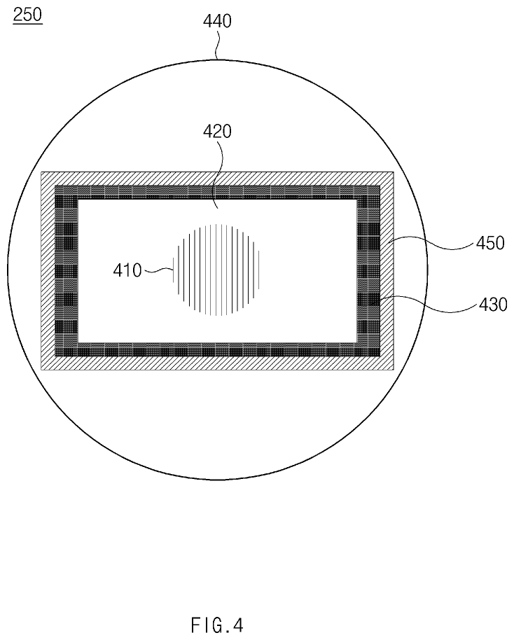

FIG. 4 is a diagram illustrating a pixel region according to an embodiment of the present disclosure.

Hereinafter, the embodiment of FIG. 4 will be described with reference to FIG. 2.

Referring to FIG. 4, the pixel region 250 according to an embodiment of the present disclosure may include an image pixel region 420, an optical black region 430, and a flare detection pixel region 450. FIG. 4 is a top view of the pixel region 250 shown in FIG. 2. In FIG. 4, an exit pupil 410 corresponding to the exit pupil 220 of FIG. 2 and an image circle 340 corresponding to the image circle 240 of FIG. 2 are illustrated.

The image pixel region 420 may be a region in which image pixels are arranged.

The optical black region 430 may represent a region including pixels that are kept in a light-blocked state. Since light is blocked, the optical black region 430 may be used to measure a black level of the image sensing device, or may be used to remove noise from the image sensing device.

The flare detection pixel region 450 may be a region in which flare detection pixels are arranged. The flare detection pixel region 450 may be disposed inside the image circle 340. In addition, the flare detection pixel region 450 may be disposed outside the optical black region 330.

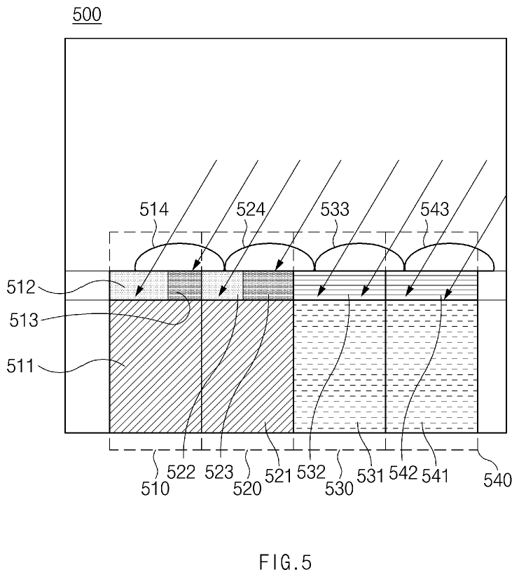

FIG. 5 is a diagram illustrating a pixel according to an embodiment of the present disclosure.

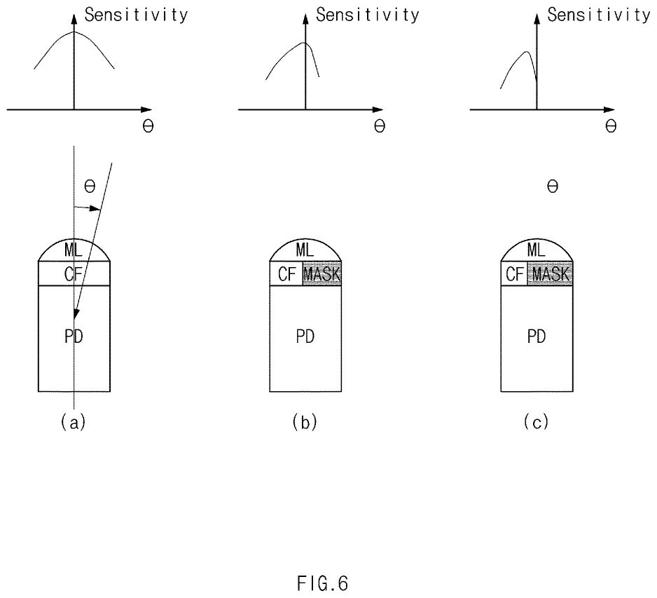

FIG. 6 is a diagram illustrating sensitivity according to an embodiment of the present disclosure.

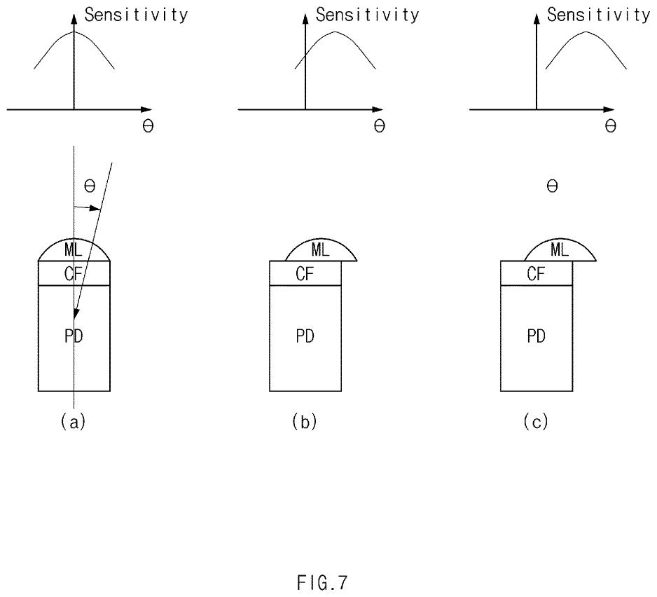

FIG. 7 is a diagram illustrating an offset according to an embodiment of the present disclosure.

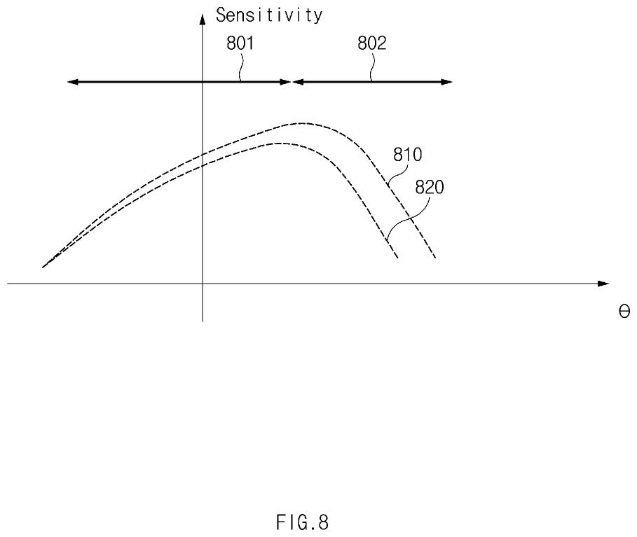

FIG. 8 is a diagram illustrating sensitivity according to an embodiment of the present disclosure.

Hereinafter, the structure of FIG. 5 will be described with reference to FIGS. 5 and 8.

Referring to FIG. 5, the image sensing device 500 may include a first flare detection pixel 510, a second flare detection pixel 520, a first image pixel 530, and/or a second image pixel 540.

The first flare detection pixel 510 may include a first flare detection photodiode 511, a first filter 512, a first mask 513, and a first microlens 514.

The first flare detection photodiode 511 may be a photodiode that generates a first flare detection signal by detecting flare light. The first flare detection photodiode 511 may be disposed inside the image circle. In addition, the first flare detection photodiode 511 may be disposed inside the optical black region and outside the image pixel region. Alternatively, the first flare detection photodiode 511 may be disposed outside the optical black region. In FIG. 5, the first flare detection photodiode 511 is illustrated as being disposed outside the first image pixel 530, but the arrangement of the first flare detection photodiode 511 according to the embodiment of the present disclosure is not limited thereto.

The first filter 512 may be disposed at an upper end of the first flare detection photodiode 511. The first filter 512 may be a transparent filter.

The first mask 513 may block a portion of light incident upon the first flare detection photodiode 511. The first mask 513 may be a metal mask. The first mask 513 may be disposed at an upper end of the first flare detection photodiode 511. Specifically, the first mask 513 may be disposed at a position closest to the exit pupil among upper regions of the first flare detection photodiode 511, without being limited thereto. Since the first mask 513 is located near the exit pupil, the first mask 513 may block a portion of light incident from the exit pupil onto the first flare detection photodiode 511. Since the first mask 513 blocks a portion of light incident from the exit pupil onto the first flare detection photodiode 511, the first mask 513 may determine the sensitivity of the first flare detection pixel 510. Specifically, referring to FIG. 6, a pixel included in the image sensing device may include a photodiode (PD), a color filter (CF), and a microlens (ML). In addition, the sizes of the masks may vary, and the sensitivity of the pixel may change depending on the size of each mask. More specifically, since the amount of light incident upon the photodiode (PD) may vary depending on the size of the mask, the sensitivity of the pixel may vary according to the size of the mask. For example, as the mask becomes larger, the amount of light incident upon the photodiode from the exit pupil or the like may decrease. Compared to (a) of FIG. 6 without a mask, the pixel sensitivity of (b) of FIG. 6 with a mask may be lower in a predetermined direction. In addition, the pixel of (c) of FIG. 6 in which the mask has a greater size than that of (b) of FIG. 6 may have lower sensitivity in a predetermined direction than the pixel of (b) of FIG. 6.

The first microlens 514 may be disposed at an upper end of the first filter 512 or the first mask 513. Specifically, the first microlens 514 may be disposed at an upper end of the first filter 512 or the first mask 513 with a predetermined offset. For example, the first microlens 514 may be disposed at a position shifted by a predetermined offset from the central axis of the first flare detection photodiode 511. The offset may indicate the degree to which the microlens is relatively shifted from the center of the pixel. Specifically, referring to FIG. 6, the angles of incidence of light incident upon the photodiodes (PDs) included in the image sensing device are different from each other, and pixel sensitivity to the incident light changes depending on the position where the microlenses (MLs) are disposed over the color filters (CF), and thus the offsets of the microlenses (MLS) included in the pixels may vary. For example, the offset of the first microlens 514 illustrated in (a) of FIG. 7 may be smaller than the offset of the first microlens 514 illustrated in (b) of FIG. 7, and the offset of the first microlens 514 illustrated in (b) of FIG. 7 may be smaller than the offset of the first microlens 514 illustrated in (c) of FIG. 7. The first microlens 514 may be arranged such that the sensitivity of the first flare detection pixel 510 increases in the direction in which light is incident upon the first flare detection photodiode 511 from the exit pupil. For example, the first microlens 514 may be disposed over the first filter 512 or the first mask 513 to have a predetermined offset corresponding to the angle of incidence of light incident from the exit pupil onto the first flare detection photodiode 511. According to an embodiment, the offset of the first microlens 514 may be determined depending on the incident angle of light such that the tangent of incident angle corresponds to the lateral displacement ratio of the first microlens 514 relative to the central axis of the first flare detection pixel 510. According to an embodiment, the offset may be pre-defined depending on the location of the exit pupil 220 and an incident angle distribution of the main lens 210.

The second flare detection pixel 520 may include a second flare detection photodiode 521, a second filter 522, a second mask 523, and a second microlens 524.

The second flare detection photodiode 521 may be a photodiode that generates a second flare detection signal by detecting flare light. The second flare detection photodiode 521 may be disposed inside the image circle. In addition, the second flare detection photodiode 521 may be disposed inside the optical black region and outside the image pixel region. Alternatively, the second flare detection photodiode 521 may be disposed outside the optical black region. In FIG. 5, the second flare detection photodiode 521 is illustrated as being disposed outside the first image pixel 530, but the arrangement of the second flare detection photodiode 521 according to the embodiment of the present disclosure is not limited thereto.

The second filter 522 may be disposed at an upper end of the second flare detection photodiode 521. The second filter 522 may be a transparent filter.

The second mask 523 may block a portion of light incident upon the second flare detection photodiode 521. The second mask 523 may be a metal mask. The second mask 523 may be disposed at an upper end of the second flare detection photodiode 521. Specifically, the second mask 523 may be disposed at a position closest to the exit pupil among upper regions of the second flare detection photodiode 521, without being limited thereto. Since the second mask 523 is located near the exit pupil, the second mask 523 may block a portion of light incident from the exit pupil onto the second flare detection photodiode 521. Since the second mask 523 blocks a portion of light incident from the exit pupil onto the second flare detection photodiode 521, the second mask 523 may determine the sensitivity of the second flare detection pixel 520. The size of the second mask 523 may be different from the size of the first mask 513. For example, the second mask 523 may be larger in size than the first mask 513. Accordingly, the amount of light incident upon the second flare detection photodiode 521 may be smaller than the amount of light incident upon the first flare detection photodiode 511. For example, referring to FIG. 8, the sensitivity 810 of the first flare detection pixel 510 may generally be greater than the sensitivity 820 of the second flare detection pixel 520. In FIG. 8, reference numeral 801 may represent a region located outside the exit pupil, and reference numeral 802 may represent a region of the exit pupil. Since the first mask 513 and the second mask 523 are disposed in a direction close to the exit pupil, the first mask 513 and the second mask 523 may block light incident from the exit pupil. Accordingly, the sensitivity 810 of the first flare detection pixel 510 and the sensitivity 820 of the second flare detection pixel 520 may be lower with respect to the exit pupil region than with respect to the outside region of the exit pupil.

The second microlens 524 may be disposed at an upper end of the second filter 522 or the second mask 523. Specifically, the second microlens 524 may be disposed at an upper end of the first filter 512 or the first mask 513 with a predetermined offset. The second microlens 524 may be arranged such that the sensitivity of the second flare detection pixel 520 increases in the direction in which light is incident upon the second flare detection photodiode 521 from the exit pupil. For example, the second microlens 524 may be disposed over the second filter 522 or the second mask 523 to have an offset corresponding to the angle of incidence of light incident from the exit pupil onto the second flare detection photodiode 521. The offset of the first microlens 514 and the offset of the second microlens 524 may be identical to each other, without being limited thereto.

The first image pixel 530 may refer to a pixel that generates a first image signal. The first image signal may be used to generate an image. The first image pixel 530 may be disposed inside the image circle.

The first image pixel 530 may include a first image photodiode 531, a third filter 532, and a third microlens 533.

The first image photodiode 531 may generate a first image signal in response to incident light.

The third filter 532 may be disposed at an upper end of the first image photodiode 531. The third filter 532 may be a color filter. Specifically, the third filter 532 may be a color filter including at least one of red, green, or blue. For example, the third filter 532 may be a green filter.

The third microlens 533 may be disposed at an upper end of the third filter 532. Specifically, the third microlens 533 may be disposed at an upper end of the third filter 532 with a predetermined offset. For example, the third microlens 533 may be arranged such that the sensitivity of the first image pixel 530 increases in the direction in which light is incident upon the first image photodiode 531 from the exit pupil. For example, the third microlens 533 may be disposed over the third filter 532 to have an offset corresponding to the angle of incidence of light incident from the exit pupil onto the first image photodiode 531. The offset of the second microlens 524 and the offset of the third microlens 533 may be identical to each other, without being limited thereto.

The second image pixel 540 may refer to a pixel that generates a second image signal. The second image signal may be used to generate an image. The second image pixel 540 may be disposed inside the image circle.

The second image pixel 540 may include a second image photodiode 541, a fourth filter 542, and a fourth microlens 543.

The second image photodiode 541 may generate a second image signal in response to incident light.

The fourth filter 542 may be disposed at an upper end of the second image photodiode 541. The fourth filter 542 may be a color filter. Specifically, the fourth filter 542 may be a color filter including at least one of red, green, or blue. For example, the fourth filter 542 may be a red filter.

The fourth microlens 543 may be disposed at an upper end of the fourth filter 542. Specifically, the fourth microlens 543 may be disposed at an upper end of the fourth filter 542 with a predetermined offset. For example, the fourth microlens 543 may be arranged such that the sensitivity of the second image pixel 540 increases in the direction in which light is incident upon the second image photodiode 541 from the exit pupil. For example, the fourth microlens 543 may be disposed over the fourth filter 542 to have an offset corresponding to the angle of incidence of light incident from the exit pupil onto the second image photodiode 541. The offset of the fourth microlens 543 and the offset of the third microlens 533 may be identical to each other, without being limited thereto.

Although not shown in FIG. 5, the image sensing device 500 may include a readout circuit. The readout circuit may generate a first flare detection pixel value based on the first flare detection signal, and may generate a second flare detection pixel value based on the second flare detection signal. In addition, the readout circuit may generate image pixel values based on the image signals.

The image processing device may determine whether flare has occurred based on the first flare detection pixel value and the second flare detection pixel value. For example, when a first ratio of a first value (obtained by subtracting a black level from the first flare detection pixel value) to a second value (obtained by subtracting a black level from the second flare detection pixel value) is less than a second threshold or greater than a third threshold, the image processing device may determine that flare has occurred. The above-described results can be expressed mathematically as represented by Equations 1 and 2.

$$\frac{( {I}_{1} - {I}_{d} )}{( {I}_{2} - {I}_{d} )} < {R}_{lower} \qquad [ Equation 1 ]$$

$$\frac{( {I}_{1} - {I}_{d} )}{( {I}_{2} - {I}_{d} )} > {R}_{upper} \qquad [ Equation 2 ]$$

In Equations 1 and 2, I₁ may represent the first flare detection pixel value, I₂ may represent the second flare detection pixel value, I_{d} may represent the black level, Rower may represent the second threshold, and Rᵤₚₚₑᵣ may represent the third threshold.

The second threshold and the third threshold may be determined based on the first flare detection pixel value and the second flare detection pixel value when flare has not occurred. For example, the second threshold may be the smallest ratio from among multiple ratios of a first value (obtained by subtracting the black level from the first flare detection pixel value) to a second value (obtained by subtracting the black level from the second flare detection pixel value) when no flare has occurred. In addition, the third threshold may be the largest ratio from among multiple ratios of a first value (obtained by subtracting the black level from the first flare detection pixel value) to a second value (obtained by subtracting the black level from the second flare detection pixel value) when no flare has occurred. The thresholds R_{lower} and Rᵤₚₚₑᵣ may be empirically determined such that the ratio

$$\frac{( {I}_{1} - {I}_{d} )}{( {I}_{2} - {I}_{d} )}$$

deviates beyond a normal luminance variation range when flare light is superimposed. For example, when flare occurs, the first pixel receives more off-axis light, resulting in a decrease of the ratio

$$\frac{( {I}_{1} - {I}_{d} )}{( {I}_{2} - {I}_{d} )} .$$

In addition, the second threshold and the third threshold may be expressed mathematically as represented by Equation 3.

$$R ( n ) = \frac{{I}_{1} ( n ) - {I}_{d}}{{I}_{2} ( n ) - {I}_{d}} \qquad [ Equation 3 ]$$

In Equation 3, I₁(n) (where n=1, 2, . . . , N) may represent the first flare detection pixel values obtained when a uniform luminance surface is captured N times, I₂(n), where n=1, 2, . . . , N, may represent the second flare detection pixel values obtained when a uniform luminance surface is captured N times, and I_{d} may represent the black level. The second threshold may be a minimum value among the R(n) values, and the third threshold may be a maximum value among the R(n) values.

In addition, the image processing device may determine whether flare has occurred based on the following equations 4 and 5.

I₁−I₂<(R_{lower}−1)(I₂−1_{d}) [Equation 4]

I₁-I₂>(Rᵤₚₚₑᵣ−1)(I₂−1_{d}) [Equation 5]

As described above, I₁ may represent the first flare detection pixel value, I₂ may represent the second flare detection pixel value, I_{d} may represent the black level, R_{lower} may represent the second threshold, and Rᵤₚₚₑᵣ may represent the third threshold.

The image processing device may determine that flare has occurred when the condition of Equation 4 or Equation 5 is satisfied.

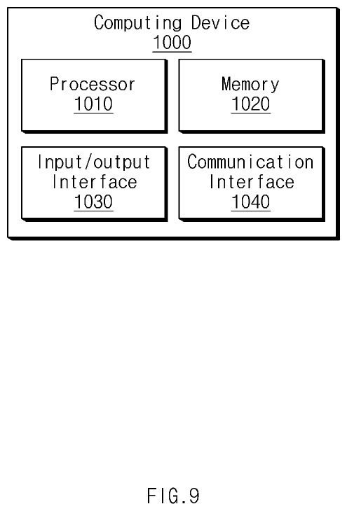

FIG. 9 is a block diagram showing a computing device corresponding to the image processing device of FIG. 1.

Referring to FIG. 9, the computing device 1000 is an embodiment of a hardware configuration for performing the operation of the image processing device 200 of FIG. 1.

The computing device 1000 may be mounted on a chip that is independent from the chip on which the image sensing device is mounted. According to one embodiment, the chip on which the image sensing device is mounted and the chip on which the computing device 1000 is mounted may be implemented in one package, for example, a multi-chip package (MCP), but the scope of the present disclosure is not limited thereto.

Additionally, the internal configuration or arrangement of the computing device 1000 and the image sensing device may vary depending on the embodiment. For example, at least a portion of the image sensing device may be included in the computing device 1000. Alternatively, at least a portion of the computing device 1000 may be included in the image sensing device. In this case, at least a portion of the computing device 1000 may be mounted together on a chip on which the image sensing device is mounted.

The computing device 1000 may include a processor 1010, a memory 1020, an input/output (I/O) interface 1030, and a communication interface 1040.

The processor 1010 may process data and/or instructions required to perform the operations of the components of the image processing device 200 described in FIG. 1.

The memory 1020 may store data and/or instructions required to perform operations of the components of the image processing device 200, and may be accessed by the processor 1010. For example, the memory 1020 may be volatile memory (e.g., Dynamic Random Access Memory (DRAM), Static Random Access Memory (SRAM), etc.) or non-volatile memory (e.g., Programmable Read Only Memory (PROM), Erasable PROM (EPROM), Electrically Erasable PROM (EEPROM), flash memory, etc.).

That is, the computer program for performing the operations of the image processing device 200 disclosed in the present disclosure may be stored in the memory 1020 and executed and processed by the processor 1010, thereby implementing the operations of the image processing device 200.

The input/output (I/O) interface 1030 may be an interface that connects an external input device (e.g., keyboard, mouse, touch panel, etc.) and/or an external output device (e.g., display) to the processor 1010 to allow data to be transmitted and received.

The communication interface 1040 is a component capable of transmitting and receiving various data to and from an external device (e.g., an application processor, external memory, etc.), and may be a device capable of supporting wired or wireless communication.

As is apparent from the above description, the imaging system according to embodiments of the present disclosure may determine whether flare has occurred by using pixel values of flare detection pixels.

Since the image sensing device according to embodiments of the present disclosure includes high-sensitivity pixels arranged in the direction in which flare light is incident, the image sensing device may accurately determine occurrence or non-occurrence of flare by using the high-sensitivity pixels.

The embodiments of the present disclosure may provide a variety of advantageous effects capable of being directly or indirectly recognized by one of ordinary skill in the art.

Those skilled in the art will appreciate that the embodiments of the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood d that modifications and enhancements to the disclosed embodiments and other embodiments can be devised based on what is described and/or illustrated in the present disclosure. Furthermore, the embodiments may be combined to form additional embodiments.

What is claimed is:

1. An image sensing device comprising:
a first flare detection photodiode;
a first mask disposed over the first flare detection photodiode;
a second flare detection photodiode disposed adjacent to the first flare detection photodiode; and
a second mask disposed over the second flare detection photodiode, the second mask having a greater area than the first mask.

2. The image sensing device according to claim 1, wherein:
the first mask is configured to block a portion of light incident upon the first flare detection photodiode from an exit pupil; and
the second mask is configured to block a portion of light incident upon the second flare detection photodiode from the exit pupil.

3. The image sensing device according to claim 1, further comprising:
a first filter disposed over the first flare detection photodiode and disposed adjacent to the first mask; and
a second filter disposed over the second flare detection photodiode and disposed adjacent to the second mask.

4. The image sensing device according to claim 3, wherein
the first filter and the second filter are transparent filters.

5. The image sensing device according to claim 1, further comprising:
a first microlens disposed over the first mask and shifted by a predetermined offset from a central axis of the first flare detection photodiode;
a second microlens disposed over the second mask and shifted by the offset from a central axis of the second flare detection photodiode;
an image photodiode configured to generate an image signal;
a third filter disposed over the image photodiode; and
a third microlens disposed over the third filter and shifted by the offset from a central axis of the image photodiode.

6. The image sensing device according to claim 5, wherein
the third filter is a color filter including at least one color of red, green, and blue.

7. The image sensing device according to claim 5, wherein
the offset corresponds to an angle of incidence of light incident upon the first flare detection photodiode, the second flare detection photodiode, and the image photodiode from an exit pupil.

8. The image sensing device according to claim 1, wherein
the first flare detection photodiode and the second flare detection photodiode are disposed inside an image circle disposed within a light incident area defined by a main lens within the image sensing device.

9. The image sensing device according to claim 8, wherein
the first flare detection photodiode and the second flare detection photodiode are disposed inside an optical black region.

10. The image sensing device according to claim 8, wherein
the first flare detection photodiode and the second flare detection photodiode are disposed outside an optical black region.

11. The image sensing device according to claim 1, wherein
the first mask is disposed at a position closest to an exit pupil among upper regions of the first flare detection photodiode.

12. The image sensing device according to claim 1, wherein
the second mask is disposed at a position closest to an exit pupil among upper regions of the second flare detection photodiode.

13. The image sensing device according to claim 1, wherein
the first mask and the second mask are metal masks.

14. An imaging system comprising:
an image sensing device including:
a first flare detection pixel including a first mask, which blocks a portion of light from an exit pupil, detects flare light, and generates a first flare detection signal,
a second flare detection pixel including a second mask, which blocks a portion of light from the exit pupil, detects the flare light, and generates a second flare detection signal, and
a readout circuit configured to generate a first flare detection pixel value based on the first flare detection signal and to generate a second flare detection pixel value based on the second flare detection signal; and
an image processing device configured to determine whether flare has occurred based on the first flare detection pixel value and the second flare detection pixel value.

15. The imaging system according to claim 14, wherein
the first flare detection pixel and the second flare detection pixel are disposed inside an image circle disposed within a light incident area defined by a main lens within the image sensing device.

16. The imaging system according to claim 15, wherein
the first flare detection pixel and the second flare detection pixel are disposed outside an optical black region.

17. The imaging system according to claim 15, wherein
the first flare detection pixel and the second flare detection pixel are disposed inside an optical black region.

18. The imaging system according to claim 14, wherein
the image processing device determines that flare has occurred when the first flare detection pixel value or the second flare detection pixel value is greater than a first threshold.

19. The imaging system according to claim 14, wherein the image processing device is configured to:
determine that the flare has occurred, when a ratio of a first value obtained by subtracting a black level of the image sensing device from the first flare detection pixel value, to a second value obtained by subtracting the black level from the second flare detection pixel value, is less than a second threshold or when the ratio of the first value to the second value is greater than a third threshold.

20. An imaging system comprising:
an image sensing device including:
a first flare detection photodiode configured to generate a first flare detection signal,
a second flare detection photodiode configured to generate a second flare detection signal,
a first mask disposed over the first flare detection photodiode,
a second mask disposed over the second flare detection photodiode, and
a readout circuit configured to generate a first flare detection pixel value based on the first flare detection signal and to generate a second flare detection pixel value based on the second flare detection signal; and
an image processing device configured to determine whether flare has occurred based on the first flare detection pixel value, the second flare detection pixel value, and a black level of the image sensing device.
